(19) United States
(12) Patent Application Publication
(10) Pub. No.: US 2011/0148513 A1
(43) Pub. Date: Jun. 23, 2011

(54) DISCRETE-TIME FILTER APPARATUS AND DISCRETE-TIME RECEIVER SYSTEM HAVING THE SAME

(75) Inventor: Young Jae LEE, Daegu (KR)

(73) Assignee: ELECTRONICS AND TELECOMMUNICATIONS RESEARCH INSTITUTE, Daejeon (KR)

(21) Appl. No.: 12/971,184

(22) Filed: Dec. 17, 2010

(30) Foreign Application Priority Data
Dec. 18, 2009 (KR) 10-2009-0127485
Nov. 17, 2010 (KR) 10-2010-0114424

(51) Int. Cl. H03K 5/00

(52) U.S. Cl. 327/552

(57) ABSTRACT

The discrete-time receiver system includes: a voltage current conversion device low-noise-amplifying an input voltage signal, and converting the amplified signal into a current signal; a first filter performing IIR filtering on the current signal output from the voltage current conversion device; a discrete-time filter performing FIR filtering on a signal output from the first filter; and a second filter performing IIR filtering on a signal output from the discrete-time filter, wherein the discrete-time filter includes a plurality of current supply units generating a current having a size obtained by multiplying an input current by a determined gain, respectively, an adding unit adding currents supplied from the plurality of current supply units, and a plurality of controllers connecting the plurality of current supply units and the adding unit and controlling the flow of current supplied from the current supply units to the adding unit.

### CROSS-REFERENCE TO RELATED APPLICATIONS

This application claims the priority of Korean Patent Application Nos. 10-2009-0127485 filed on Dec. 18, 2009 and 10-2010-0114424 filed on Nov. 17, 2010, in the Korean Intellectual Property Office, the disclosures of which are incorporated herein by reference.

### BACKGROUND OF THE INVENTION

1. Field of the Invention

The present invention relates to a discrete-time filter and, more particularly, to a discrete-time filter using a switch and a capacitor in a semiconductor circuit field.

2. Description of the Related Art

A digital radio frequency (RF) technique is based on a discrete-time signal processing scheme which may be able to fully utilize a high speed switching operation of accurate timing, one of the merits of a complementary metal oxide semiconductor (CMOS) process. Also, in the digital RF technique, a basic philosophy allows for rapidly developed corresponding designs when a process adopted for a design is shifted to a new process.

An FIR filter designed by using such a digital RF technique may be one of two typical types: an FIR (Finite Impulse Response) filter structure for adjusting a decimation rate by regulating the operation of switches in a state in which capacitors and the switches are connected; and an FIR filter structure including a switch and an integrator.

The first type of FIR filter structure, which uses only a lumped element, is advantageous in that the decimation rate thereof can be easily adjusted and the structure is simple, although a pulse generator, provided to generate pulses for regulating the respective switches, may be complicated.

The second type of FIR filter structure is disadvantageous in that a great amount of power is consumed due to the presence of an amplifier used for the integrator, and it is difficult to adjust the decimation rate.

The second type of FIR filter structure has better anti-aliasing filtering performance than the first type of FIR filter structure; however, the differences therebetween are insignificant.

FIG. 1 is a schematic block diagram showing the structure and operation of an RF front end (RFE) implemented by using capacitors and switches frequently used in a discrete-time receiver.

With reference to FIG. 1A, a voltage signal input through an antenna is amplified through a low noise amplifier and then converted into a current signal through a trans-conductance amplifier 110.

The current signal is frequency-converted through a sampling mixer 120 and charges the sampling capacitor 130.

The sampling capacitor 130 operates as an IIR (Infinite Impulse Response) filter.

An FIR filter 140 includes switches S[0] and S[1], rotary capacitors CR1 and CR2, and switches SA and B, and performs decimation and anti-aliasing.

The capacitor bank 150 operates as an IIR filter, and a cut-off frequency of the IIR filter can be adjusted by tuning. A filtered signal is amplified by using a buffer 160 whose gain is variable, and then input to an ADC.

FIG. 1B is a timing diagram of clocks input to each switch of FIG. 1A.

Clocks LO_P and LO_N are input to a sampling mixer, and accordingly clocks SA and SB are determined. Clock D is used to control the inputting of an electric charge charged in C_{B} of the FIR filter to the IIR filter.

FIG. 2A is a circuit diagram of a circuit implementing an FIR filter by using an active circuit.

With reference to FIG. 2A, a current signal, which has passed through a trans-conductance amplifier 210 and a mixer 220, is input to respective discrete-time filters 230, 240, 250, and 260. The FIR filter includes an integrator and an input/output (I/O) switch.

A sampling frequency and decimation rate of the FIR filter may be regulated by adjusting the number of units, and in FIG. 2A, the number of units is 2 (230 and 240, 250 and 260), respectively.

The integrator has a structure in which a reset switch is connected in parallel to a sampling capacitor Cₛ. Input and output switches Pin and Pout are disposed at front and rear stages of the integrator.

FIG. 2B is a timing diagram of clocks used for operating each switch of FIG. 2A.

With reference to FIG. 2B, respective FIR filter units of FIG. 2A perform a time-interleave charge sampling function.

The first and second units 230 and 240 alternately charge and output electrical charges. In detail, after the first unit 230 charges a sampling capacitor with electrical charges, it outputs the electrical charges during a half clock, at a time at which the second unit 240 charges the sampling capacitor with electrical charges, and discharges remaining electrical charge by using a reset switch. Also, the second unit 240 also charges, outputs, and discharges electrical charges, like the first unit 230.

Advantageously, the sampling frequency is doubled by using the two units and the decimation rate thereof is 2.

However, the foregoing structures have problems in that a buffer block is required in order to change a current gain and making a DC offset connection is difficult.

### SUMMARY OF THE INVENTION

An aspect of the present invention provides a discrete-time filter whose decimation rate can be freely adjusted and in which a current gain can be regulated, and a discrete-time receiver system using the same.

According to an aspect of the present invention, there is provided a discrete-time filter including: a plurality of current supply units generating a current having a size obtained by multiplying an input current by a determined gain, respectively; an adding unit adding currents supplied from the plurality of current supply units; and a plurality of controllers connecting the plurality of current supply units and the adding unit and controlling the flow of current supplied from the current supply units to the adding unit.

According to another aspect of the present invention, there is provided a discrete-time filter including: a current supply unit generating a current having a size obtained by multiplying an input current by a determined gain; an adding unit adding current supplied from the current supply unit; and a controller connecting the current supply unit and the adding unit and controlling the flow of current supplied from the current supply unit to the adding unit, wherein a plurality of structures, each in which the current supply unit, the adding unit, and the controller are connected in series, are connected in parallel.

According to another aspect of the present invention, there is provided a discrete-time receiver system including: a voltage current conversion device low-noise-amplifying an input voltage signal, and converting the amplified signal into a current signal; a first filter performing IIR (Infinite Impulse Response) filtering on the current signal output from the voltage current conversion device; a discrete-time filter performing FIR (Finite Impulse Response) filtering on a signal output from the first filter; and a second filter performing IIR filtering on a signal output from the discrete-time filter, wherein the discrete-time filter includes a plurality of current supply units generating a current having a size obtained by multiplying an input current by a determined gain, respectively, an adding unit adding currents supplied from the plurality of current supply units, and a plurality of controllers connecting the plurality of current supply units and the adding unit and controlling the flow of current supplied from the current supply units to the adding unit.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view illustrating the structure and an operation of an RFE (RF front-end) implemented by using capacitors and switches frequently used in an existing discrete-time receiver;

FIG. 2A is a circuit diagram of a circuit implementing an FIR filter by using an active circuit;

FIG. 2B is a timing diagram of clocks for operating each switch of FIG. 2A;

FIG. 3A is a function block diagram of a discrete-time filter according to an exemplary embodiment of the present invention;

FIG. 3B is a circuit diagram of a discrete-time filter employing a current mirror structure according to an exemplary embodiment of the present invention;

FIG. 3C is a view showing an example of an implementation of a discrete-time filter according to an exemplary embodiment of the present invention;

FIGS. 4A to 4C are views showing another example of an implementation of a discrete-time filter according to an exemplary embodiment of the present invention;

FIG. 5 is a view showing another example of an implementation of a discrete-time filter according to an exemplary embodiment of the present invention;

FIGS. 6A and 6B are views showing another example of an implementation of a discrete-time filter according to an exemplary embodiment of the present invention;

FIG. 7 is a view showing an example of an RF reception end using a discrete-time filter; and

FIG. 8 is a graph showing simulation results of the RF reception end of FIG. 7.

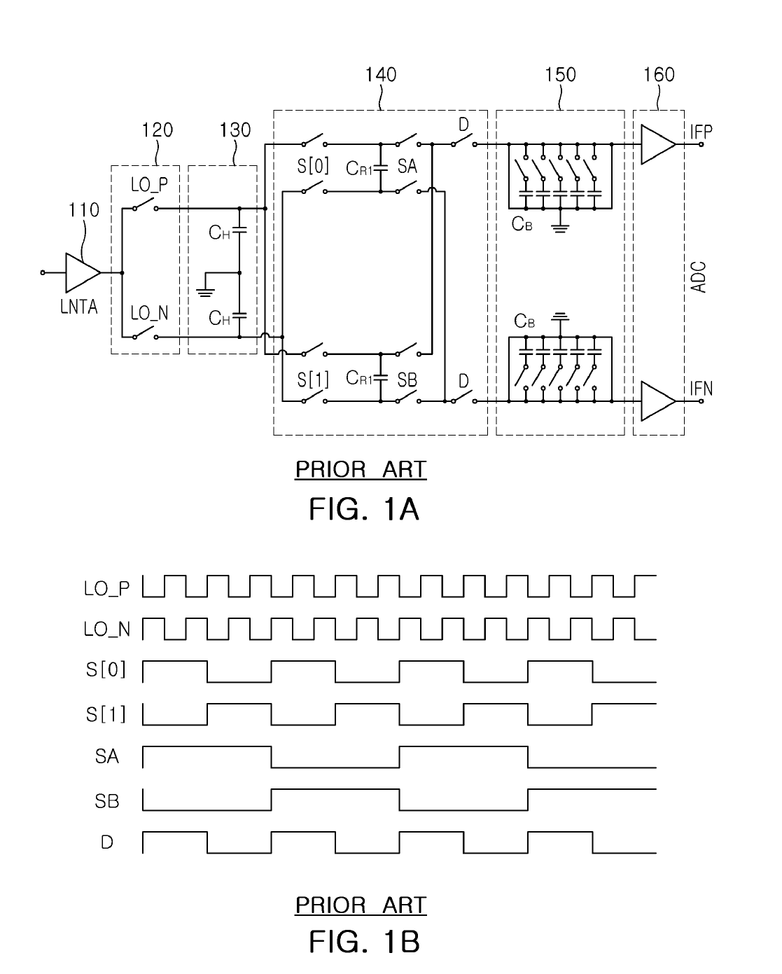

### DETAILED DESCRIPTION OF THE PREFERRED EMBODIMENT

Exemplary embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art.

In the drawings, the shapes and dimensions may be exaggerated for clarity, and the same reference numerals will be used throughout to designate the same or like components.

Unless explicitly described to the contrary, the word “comprise” and variations such as “comprises” or “comprising,” will be understood to imply the inclusion of stated elements but not the exclusion of any other elements.

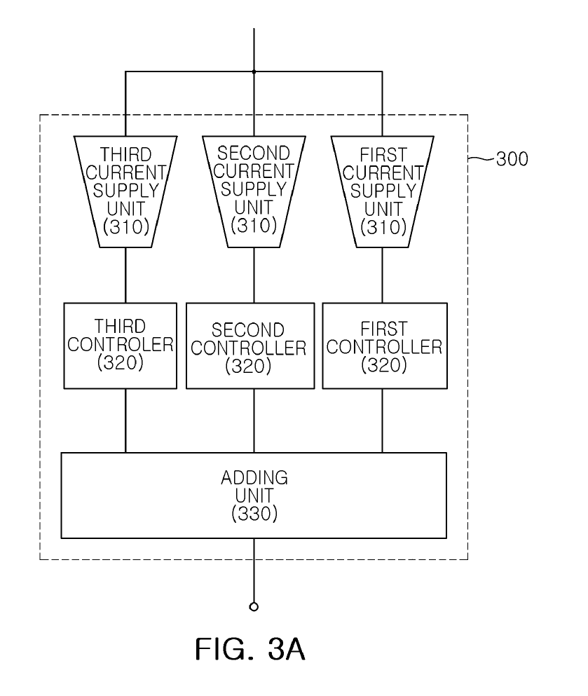

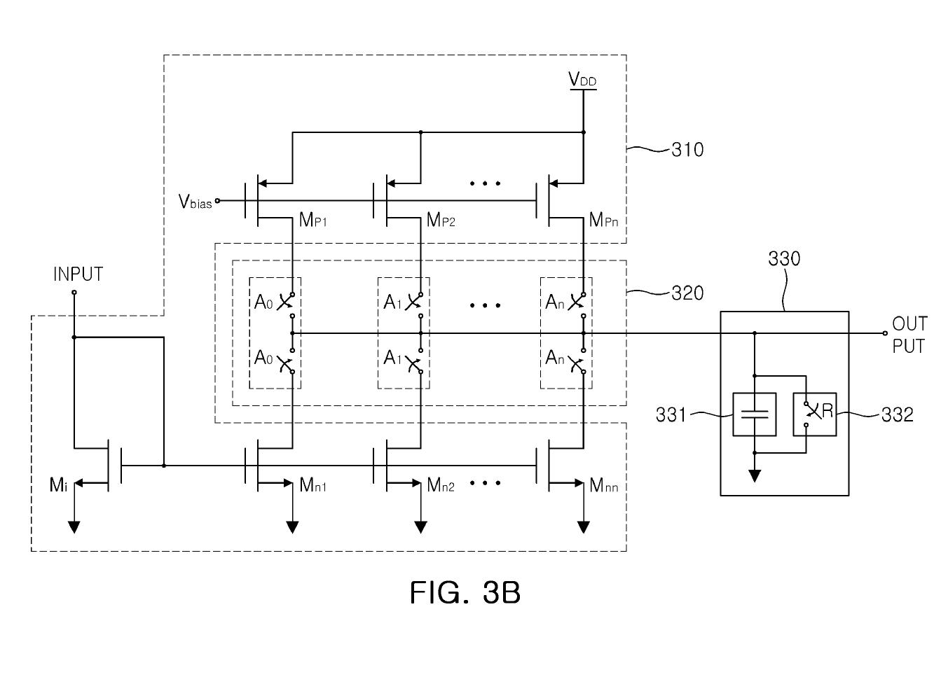

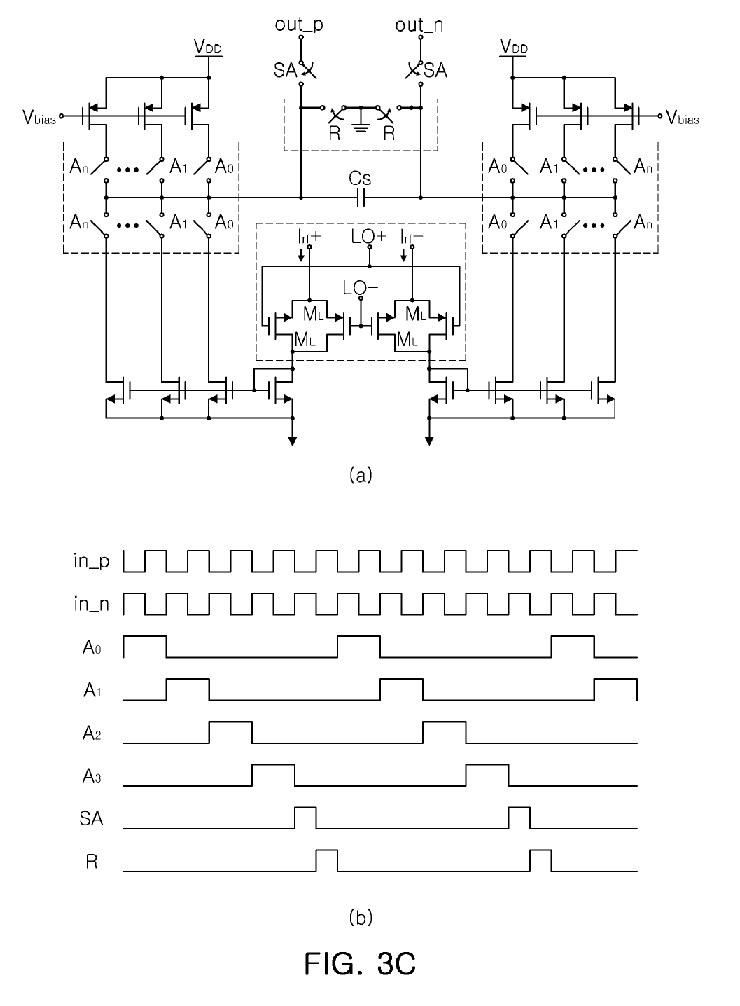

FIG. 3A is a function block diagram of a discrete-time filter according to an exemplary embodiment of the present invention.

With reference to FIG. 3A, a discrete-time filter 300 may include a plurality of current supply units 310, controllers 320, and an adding unit 330.

The current supply units 310 generate a current obtained by multiplying the size of input current by a determined gain. The current generated by the current supply units 310 is supplied to the adding unit 330 under the control of the controller 320. Apart from the input current, because the current supply units 310, which generate current to be used for filtering, are provided, a current gain can be controlled only with the discrete-time filter without having to use a buffer unit for changing a current gain. Also, because a unit for regulating bias in a generated current is provided, the discrete-time filter and a DC bias control device can be easily connected. The number of the current supply units 310 may be determined in consideration of a decimation rate and a current gain as required.

The controllers 320, connecting the current amplifying units 310 and the adding unit 330, control the flow of current supplied from the current supply units 310 to the adding unit 330.

The adding unit 330 adds the current supplied from the current supply units 310 through the controllers 320. The added current is transmitted to a next stage by an output switch.

The discrete-time filter performs discrete-time filtering with respect to an input signal by using the control controlling performed by the controllers 320 and the addition performed by the adding unit 330. Thus, a cut-off frequency or the like can be regulated by adjusting the current control method of the controllers 320 and the structure of the adding unit 330.

FIG. 3B is a circuit diagram of a discrete-time filter employing a current mirror structure according to an exemplary embodiment of the present invention.

With reference to FIG. 3B, the discrete-time filter according to an exemplary embodiment of the present invention may include a current supply unit 310 using a current mirror structure, a controller 320 controlling a flow of current from the current supply unit by using a switch, and an adding unit 330 adding current supplied from the current supply unit 310 through the controller 320.

The current supply unit 310 may be implemented through a current mirror structure.

A DC bias of current can be changed by changing a voltage Vbias applied to gate terminals of PMOS (Mₚ₁, Mₚ₂, . . . Mₚₙ).

Thus, because the amount of an output current can be regulated by adjusting an amplification rate value of each transistor, the current gain can be changed in the discrete-time filter. Also, because the DC bias of the current supplied to the filter can be adjusted at a load where all the currents are added, before being connected to the adding unit, its connection to a DB bias control circuit can be facilitated.

The controller 320 may include switches controlled by clocks. The respective switches are controlled by using clock signals (A₀, A₁, . . . Aₙ) which have the same period but are delayed by each different sampling period. The switches of the controller 320 are disposed between one NMOS and one PMOS, respectively, to control current flowing from the current supply unit 310 to the adding unit 330.

The adding unit 330 may include a charger 331 and a discharger 332.

The charger 331 serves to temporally add current supplied from the plurality of current supply units 310. In general, the charger 331 may be implemented as a capacitor or a capacitor bank. When the charger 331 is implemented as a capacitor, it charges electrical charges and outputs electrical charges, so the charger 331 may perform the function of adding currents and outputting the added current.

The discharger 332 serves to set the current added in the charger 331 according to a certain period. When the charger is implemented as a capacitor, or the like, as mentioned above, paths for shorting both ends of the capacitor may be formed and switches for performing a controlling operation may be disposed on the paths. The switches may operate according to a reset clock.

When the discrete-time filter 300 performs discrete-time filtering (namely, FIR filtering), a clock period and a delay time of clocks of the controller 320 and a clock of the discharger 332, are determined according to a decimation rate.

Also, the current supply unit 310, which is not used for filtering to change a current gain, as well as the current supply unit 310 used for filtering, may also be controlled to supply current to the adding unit 330 when current from the current supply unit 310 used for filtering is supplied to the adding unit 330.

For example, it is assumed that filtering is performed by using the discrete-time filter 300 having four current supply units 310 and only two current supply units 310 are used for filtering; however, three current supply units 310 are required to supply current in order to meet the requirements of the current gain. In this case, the third and fourth current supply units 310 are controlled to supply current to the adding unit at a time at which the first current supply unit 310 supplies current to the adding unit, thus performing filtering while satisfying the requirements of the current gain.

Namely, the discrete-time filter according to an exemplary embodiment of the present invention is a discrete-time filter in which a decimation rate can be adjusted by regulating the period and delay time of each clock. Also, in the discrete-time filter according to an exemplary embodiment of the present invention, the current gain can be regulated by adjusting the amplification rate of each transistor of the current supply unit or the number of operating transistors. Also, because the DC bias of the current supplied to the filter can be adjusted at a load where all the currents are added, before being connected to the adding unit, its connection to a DB bias control circuit can be facilitated.

FIG. 3C is a view showing an example of an implementation of a discrete-time filter according to an exemplary embodiment of the present invention.

With reference to FIG. 3C, the discrete-time filter according to the present exemplary embodiment includes two input signals and circuits being configured in parallel.

The two input signals in_p and in_n of the discrete-time filter illustrated in FIG. 3C(a) are signals obtained by sampling positive (+) and negative (−) output signals of a trans-conductance amplifier by using a clock having a phase difference of a half period, respectively. The input signal in_p is filtered into an output signal out_p and the input signal in_n is filtered into an output signal out_n.

FIG. 3C(b) is a time diagram implementing a discrete-time filter in which a decimation rate is 5 by adjusting the period and a delay time of the clocks for controlling the respective switches of the controller and the reset clock.

As for the switch clocks and the reset clock, five sampling clocks in_p are set as one period in order to obtain the decimation rate of 5. Also, the duration in which signals of the switch clocks are turned on is 1 sampling clock im_p. As for a delay time, the discrete-time filter is designed as a primary decimation filter so that the signals of the switch clocks are turned as the switch clocks are delay by 1 sampling clock in_p.

Electrical charges are charged in the adding unit according to the operation of the switch clocks. When charging of the adding unit is completed according to the operation of the switch clocks, electrical charges charged in the adding unit are delivered to an output terminal during a sampling clock of one half period. During a sampling clock of another half period, the discharge unit discharges the electrical charges charged in the adding unit.

Because an input signal is converted into a single output signal during the five sampling clocks, the decimation rate is 5 and FIR filtering takes place in terms of physical qualities of the capacitor.

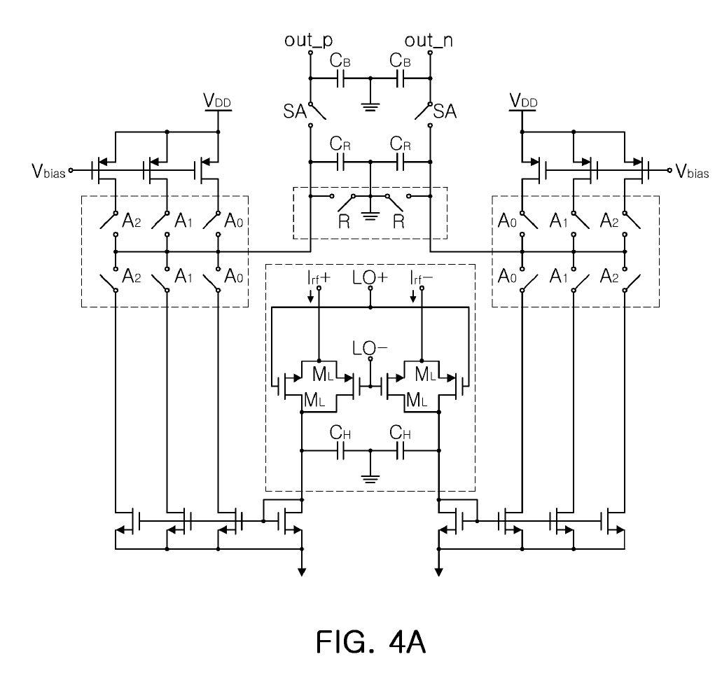

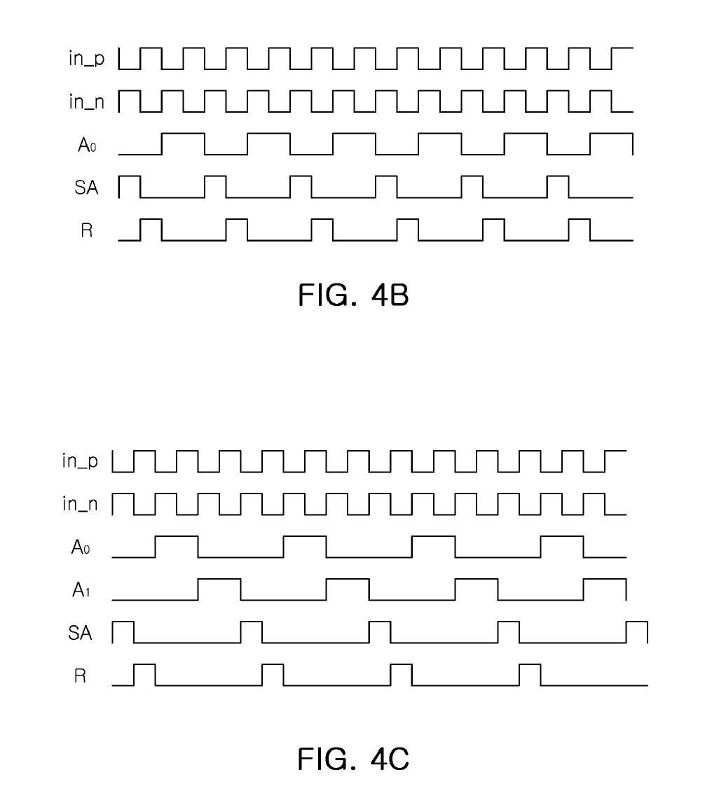

FIGS. 4A to 4C are views showing another example of an implementation of a discrete-time filter according to an exemplary embodiment of the present invention.

The discrete-time filter as shown in FIG. 4A is implemented to be the same as the discrete-time filter illustrated in FIG. 3C, except that n in the discrete-time filter in FIG. 3C is replaced by 3.

The current supply unit is configured to have three current mirror structures and to have three current paths. The three current mirror structures may be partially or entirely operated as necessary.

FIGS. 4B and 4C are timing diagram of the clocks of each part for operating the filter of FIG. 4A.

Specifically, FIG. 4B shows an FIR filter having a decimation rate of 2 and FIG. 4C shows an FIR filter having a decimation rate of 3.

In the FIR filter illustrated in FIG. 4B, only one of the three current paths of the current supply unit is used. In the FIR filter illustrated in FIG. 4C, only two of the three current paths of the current supply unit are used. The current path not in use may be used to regulate the current gain of the discrete-time filter.

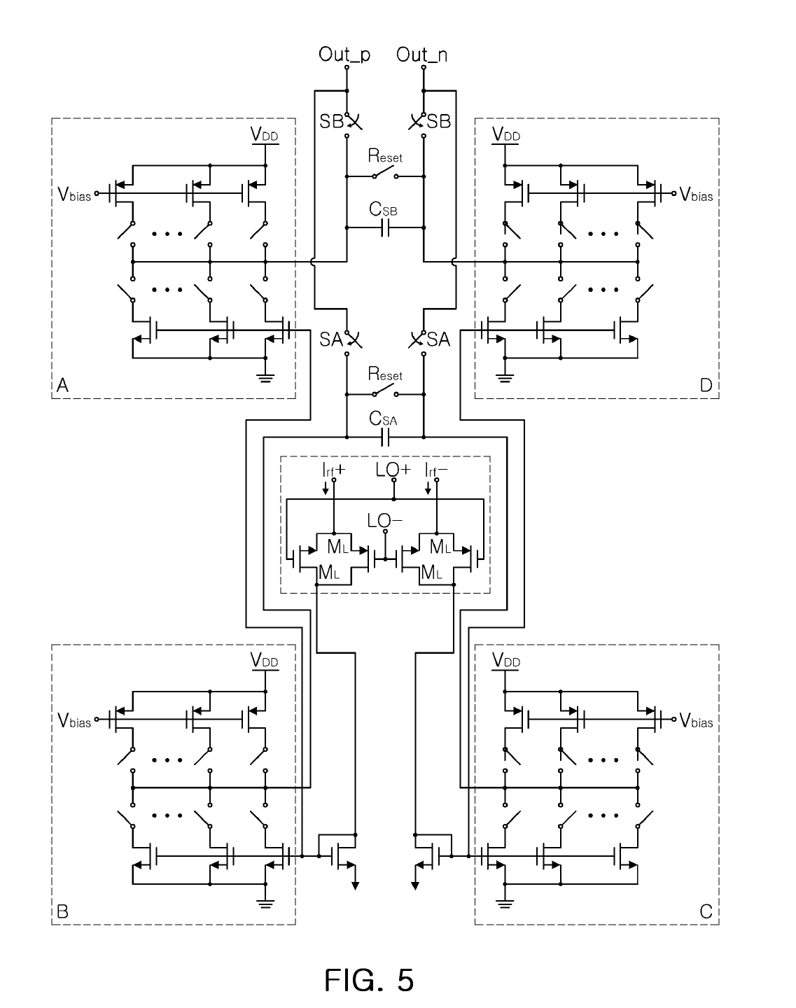

FIG. 5 is a view showing another example of an implementation of a discrete-time filter according to an exemplary embodiment of the present invention.

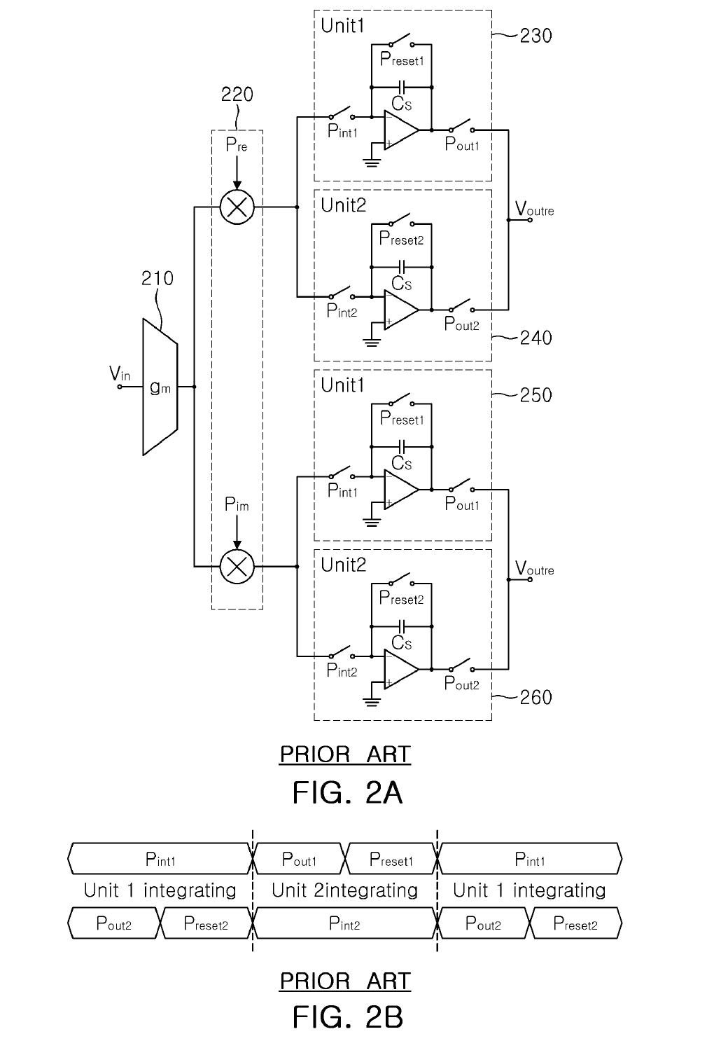

The discrete-time filter illustrated in FIG. 5 is implemented to have two units illustrated in FIG. 2 by using the structures proposed in FIG. 4.

The input current in_p is transmitted to current supply units A and B. Current generated by a current supply unit A is supplied to an adding unit A, and current generated by a current supply unit B is supplied to an adding unit B. Current added in each adding unit is output through a single output terminal.

Current supply units C and D, which receive the input current in_n, perform the same operations as those of the current supply units A and B while having only a phase delay of a sampling clock of a half period.

Double sampling can be performed by implementing the discrete-time filter with two units.

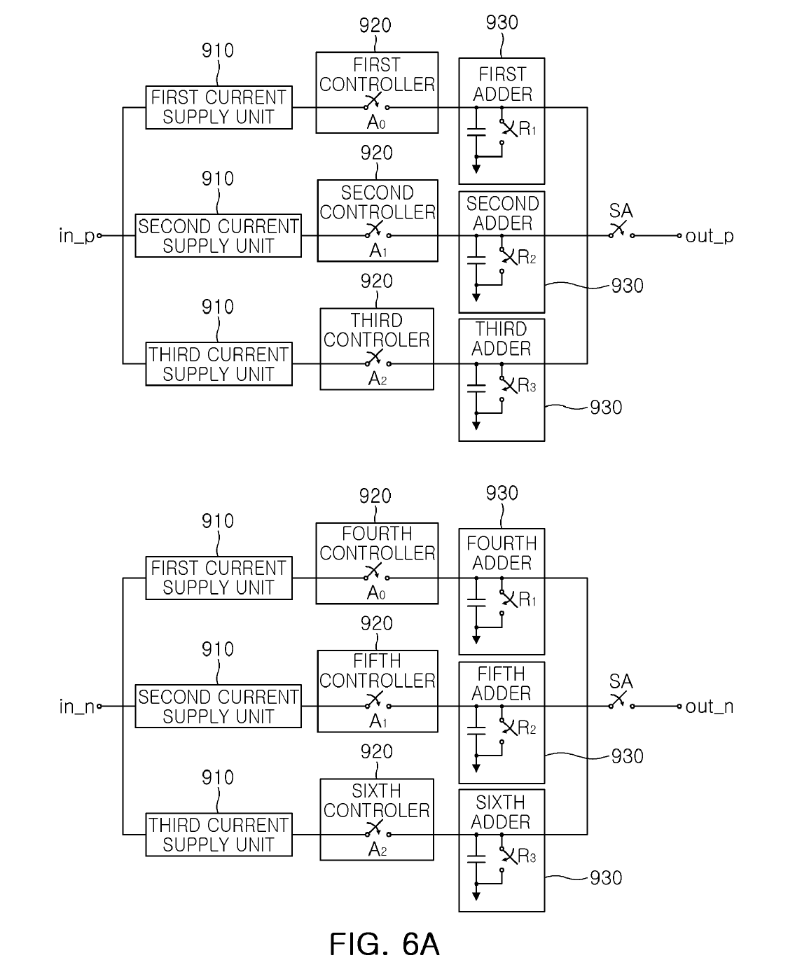

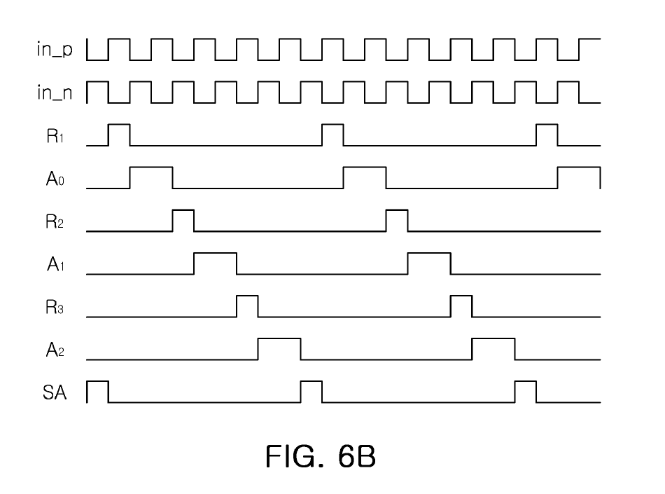

FIGS. 6A and 6B are views showing another example of an implementation of a discrete-time filter according to an exemplary embodiment of the present invention.

With reference to FIG. 6A, the discrete-time filter according to the present exemplary embodiment may be configured to include a plurality of current supply units 910, a plurality of controllers 920, and a plurality of adding units 920. The structures, each in which the current supply unit 910, the controller 920, and the adding unit 930 are connected in series, may be connected in parallel.

By having such a parallel structure, a secondary FIR filer can be implemented. The currents supplied from the respective current supply units 910 are temporally added in the respective adding units 930. Thus, a transfer function of the secondary FIR filter can be implemented by regulating the ratio of the currents supplied from the respective current supply units 910 or regulating the respective adding units. This is because, in order to become the secondary FIR filter, the weights with respect to the signals in the transfer function must be symmetrical.

FIG. 6B is a timing diagram for the circuit illustrated in FIG. 6A to operate as the secondary FIR filter.

With reference to FIG. 6A, the FIR filter has a weight value of 1-2-1, and the currents supplied from the respective current supply units 910 are added in the respective adding units 930. The currents added in the respective adding unit 930 are output through a single output unit.

Although not shown, the generally used secondary filter having a weight value 1-3-5-3-1 may be implemented to include five current supply units 910, five controllers 920, and five adding units 390.

The secondary FIR filter may be implemented to have a different weight by regulating the ratio of the currents supplied from the respective current supply units or regulating the respective adding units. In this case, a sampling frequency, which is double that of the primary FIR filter, is required for implementing the secondary FIR filter.

Thus, because the secondary FIR filter is implemented thusly as described above, the width of null can be widened and the depth of null can be deepened, thus increasing an anti-aliasing effect.

Also, when the secondary FIR filter is implemented only with the current supply units 910 having a plurality of same current gains, a set of current supply units that supply current according to each clock with the same ratio of the weight ratio may be formed and controlled. For example, when a current weight is 1, current from one current supply unit 910 may be controlled to flow to the adding unit 930 and when the current weight is 3, currents from three supply units 910 may be controlled to flow to the adding unit 930 at each timing.

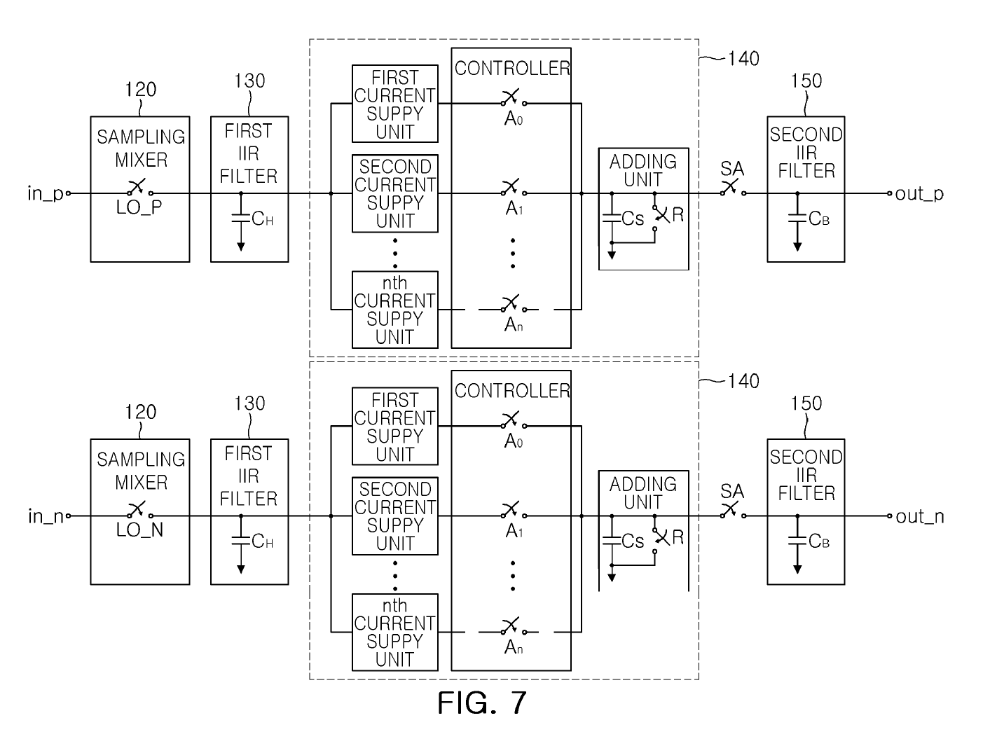

FIG. 7 is a view showing an example of an RF reception end using a discrete-time filter.

With reference to FIG. 7, a low-noise amplifier and a trans-conductance amplifier are not shown, and in an RF reception end according to the present exemplary embodiment, a discrete-time filter having a current supply unit using a current mirror structure is used as an FIR filter. The discrete-time filter has a parallel structure which receives positive (+) and negative (−) output signals of the trans-conductance amplifier, respectively.

A CMOS switch is used as the sampling mixer 120, and a sampling clock is input to a gate terminal of the sampling mixer 120. An input signal can be sampled by turning on or off the switch according to the sampling clock.

The first IIR filter 130 is implemented to have one capacitor C_{H} connecting a ground and a current path.

The FIR filter 140 is implemented by using the discrete-time filter using the current supply unit, the control unit, and the adding unit according to an exemplary embodiment of the present invention. For example, the FIR filter 300 may be implemented by using the filter illustrated in FIG. 6 or FIG. 9.

The operation of the discrete-time filter has been described in detail, so a repeated description thereof will be omitted.

The current added in the FIR filter 140 is delivered to the second IIR filter 150 by a switch operated by a clock.

The second IIR filter 150 is implemented to have one capacitor CB connecting a ground and the current path.

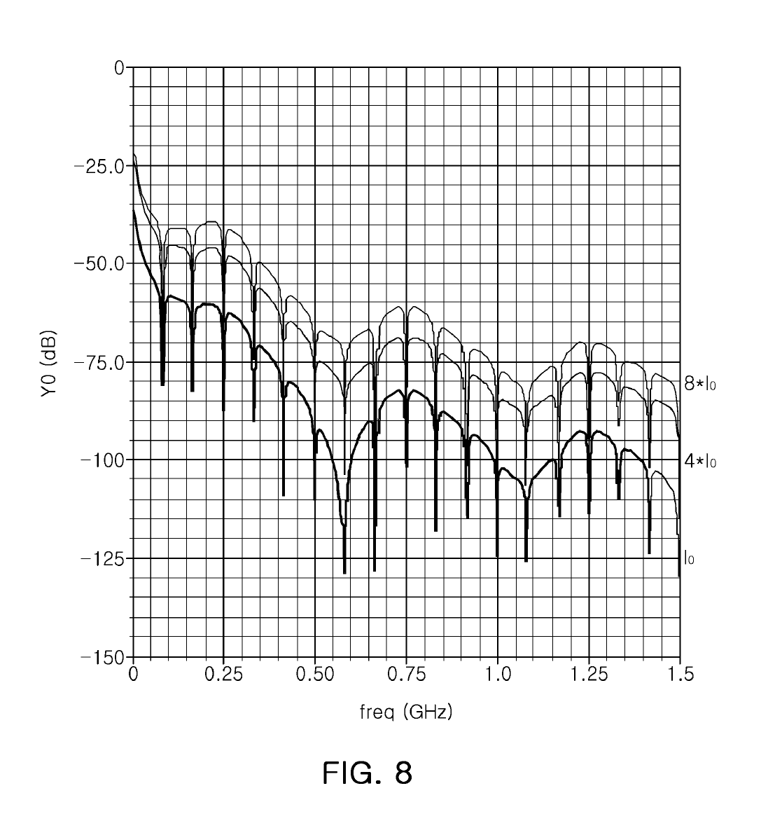

FIG. 8 is a graph showing simulation results of the RF reception end of FIG. 7.

The circuit simulation was performed by using a decimation rate of 3 over a 250 MHz sampling frequency. Gains were obtained according to the frequencies of output waveforms of the results obtained by performing both the FIR and IIR filtering.

Also, it is noted that the gains of the output waveforms were increased to 12 dB and 6 dB when a four-fold and 8-fold current were supplied from the current supply unit 910.

As set forth above, in the discrete-time filter and the discrete-time receiver system according to exemplary embodiments of the invention, the degree and a decimation rate of the filter can be adjusted by regulating a delay time between period clocks of clocks input to a fixed circuit.

In addition, a connection to a DC offset control device can be facilitated, and the current gain of the overall filer can be varied.

While the present invention has been shown and described in connection with the exemplary embodiments, it will be apparent to those skilled in the art that modifications and variations can be made without departing from the spirit and scope of the invention as defined by the appended claims.

What is claimed is:

1. A discrete-time filter comprising:
a plurality of current supply units generating a current having a size obtained by multiplying an input current by a determined gain, respectively;
an adding unit adding currents supplied from the plurality of current supply units; and
a plurality of controllers connecting the plurality of current supply units and the adding unit and controlling the flow of current supplied from the current supply units to the adding unit.

2. The discrete-time filter of claim 1, wherein the plurality of current supply units are implemented to have a current mirror structure, and an input current is applied to one end of the current mirror structure.

3. The discrete-time filter of claim 2, wherein the current mirror structures of the plurality of current supply units have the same current gain or different gains.

4. The discrete-time filter of claim 1, wherein the controller comprises a switch, the switch connects one of the current supply units and the adding unit, and the operations of the respective switches of the plurality of controllers are determined by control signals delayed by different sampling periods and having the same period.

5. The discrete-time filter of claim 4, wherein the periods of control signals of the controllers and a delay time between control signals of the respective controllers are determined according to a decimation rate.

6. The discrete-time filter of claim 1, wherein the adding unit comprises:
a charger charging electrical charges by using the current supplied from the current supply units; and
a discharger discharging the electrical charges from the charger according to a reset signal.

7. The discrete-time filter of claim 6, wherein the period of the reset signal of the discharger is determined according to a decimation rate.

8. A discrete-time filter comprising:
a current supply unit generating a current having a size obtained by multiplying an input current by a determined gain;
an adding unit adding current supplied from the current supply unit; and
a controller connecting the current supply unit and the adding unit and controlling the flow of current supplied from the current supply unit to the adding unit,
wherein a plurality of structures, each in which the current supply unit, the adding unit, and the controller are connected in series, are connected in parallel.

9. The discrete-time filter of claim 8, wherein the plurality of current supply units are implemented to have a current mirror structure, and an input current is applied to one end of the current mirror structure.

10. The discrete-time filter of claim 9, wherein the current mirror structures of the plurality of current supply units have the same current gain or different gains.

11. The discrete-time filter of claim 10, wherein the controller comprises a switch connecting the current supply unit and the adding unit, and the operations of the respective switches of the plurality of controllers are determined by control signals delayed by different sampling periods and having the same period.

12. The discrete-time filter of claim 11, wherein the periods of clocks and a delay time between switches are determined according to a decimation rate.

13. The discrete-time filter of claim 8, wherein the adding unit comprises:
a charger charging electrical charges by using the current supplied from the current supply units; and
a discharger discharging the electrical charges from the charger according to a reset signal delayed by a different sampling period and having the same period in each adding unit.

14. The discrete-time filter of claim 13, wherein the period of the reset signal of the discharger and the degree of delay of a reset timing of the discharger of each adding unit are determined according to a decimation rate.

15. A discrete-time receiver system comprising:
a voltage current conversion device low-noise-amplifying an input voltage signal, and converting the amplified signal into a current signal;
a first filter performing IIR (Infinite Impulse Response) filtering on the current signal output from the voltage current conversion device;
a discrete-time filter performing FIR (Finite Impulse Response) filtering on a signal output from the first filter; and
a second filter performing IIR filtering on a signal output from the discrete-time filter,
wherein the discrete-time filter includes a plurality of current supply units generating a current having a size obtained by multiplying an input current by a determined gain, respectively, an adding unit adding currents supplied from the plurality of current supply units, and a plurality of controllers connecting the plurality of current supply units and the adding unit and controlling the flow of current supplied from the current supply units to the adding unit.

16. The system of claim 15, wherein the first and second filters are implemented to have a charge area filter, respectively.

17. The system of claim 15, wherein the plurality of current supply units are implemented to have a current mirror structure, and an input current is applied to one end of the current mirror structure.

18. The system of claim 17, wherein the current mirror structures of the plurality of current supply units have the same current gain or different gains.
